(19) United States
(12) Patent Application Publication
(10) Pub. No.: US 2014/0096696 A1
(43) Pub. Date: Apr. 10, 2014

(54) OPEN LOOP CONTROL SYSTEM AND METHODS FOR COLOR PRINT REGISTRATION

(71) Applicant: NELA Ternes Register Group, Inc., River Falls, WI (US)

(72) Inventors: Robert M. Deis, Hudson, WI (US); William Earl Morren, River Falls, WI (US)

(73) Assignee: NELA Ternes Register Group, Inc., River Falls, WI (US)

(21) Appl. No.: 14/046,373

(22) Filed: Oct. 4, 2013

Related U.S. Application Data
(60) Provisional application No. 61/710,336, filed on Oct. 5, 2012.

(51) Int. Cl. G03F 9/00

(52) U.S. Cl. CPC G03F 9/00
USPC 101/481

(57) ABSTRACT

Systems and methods for controlling a printing press operation for alignment of plural images as are superposed onto one another. Plural images are aligned to one another as part of a color printing operation utilizing plural printing stations where registration marks associated with the plural respective images can be aligned to one another based upon an open loop feedback of registration information. One or more data sources, such as cameras, capture the registration marks and digitize the data so that alignment or misalignment can be determined based upon tolerance limits. Systems and methods of the present invention provide for real-time monitoring of image alignment so that an operator can quickly and easily make adjustments to printing cylinders to correct image alignment.

### CROSS REFERENCE TO RELATED APPLICATION

This application claims the benefit of U.S. Provisional Patent Application No. 61/710,336, filed Oct. 5, 2012 and titled “OPEN LOOP CONTROL SYSTEM AND METHODS FOR COLOR PRINT REGISTRATION” which application is incorporated herein by reference in its entirety.

### TECHNICAL FIELD

The present invention is directed to control systems and methods of controlling a plurality of printing press operations, such as are utilized for color printing, for registering one image to another from respective printing press stations. In particular, the present invention is directed to control systems and methods of plural printing stations where registration marks associated with plural respective images can be aligned to one another based upon an open loop feedback of registration information.

### BACKGROUND

High-speed web press operations are commonly used to print multi-color images such as those used in newspapers, commercial printing and the like. In such operations, individual lithographic plates are used to print the different colors found in a multi-color image. Such multi-color images therefore comprise a superimposed color image. The lithographic plates are carefully mounted on a printing press with respect to each other so that the individual color images formed on the printed surface are sufficiently registered to provide the desired clarity and sharpness in the final superimposed image. Otherwise, the final image can have ghost-like characteristics as a result of any plate misalignment.

A typical lithographic plate includes features such as flanges and openings that enable it to be mounted on a printing plate cylinder of a printing press. The configuration of these flanges and openings defines the alignment between plural plates installed on a printing press and provides the registration of the printed image. Accordingly, precision metal working techniques for bending such flanges and forming such openings are used to ensure precision alignment between plural plates mounted on a printing press.

A web material, such as newspaper or other paper stock from rolls, typically is printed on both sides thereof while passing through a printing press having a print cylinder to each side of the web material. For color printing, the web material is sequentially passed though similar arrangements of print cylinders as such print cylinders are provided within each of a plurality of printing press stations. Typically, a printing station that includes opposed print cylinders is provided for each color so as to print both sides of a paper web with four such stations provided inline as the paper web travels so as to print four colors as are known to provide multi-color images. Usual colors for printing multi-color images include cyan, magenta, yellow and black (CMYK), which colors need to be correctly superposed upon one another with respect to registration of each color image to the others for multi-color superposed images. Printing systems can also use more colors than the noted four, and many printing operations utilize up to seven different colors. Such printing stations can be stacked in print towers including any plurality of color stations, for example, including four color stations for a CMYK print operation.

Adjustments of print cylinders of one color to another are typically provided for within such printing stations for the purpose of controlling the image positioning onto the web material as it passes. Specifically, it is typical to provide for cylinder vertical or up/down adjustment and cylinder side to side adjustment. Many print presses used within the industry today utilize manual adjustment of the print cylinders in both of these directions, such as by way of hand cranks Other adjustment methods for print presses utilize motors for shifting any number of print cylinders as may be controlled, for example, at a console by an operator.

In order to effect adjustment by way of an operator, each color image is printed onto the moving web. The goal would be that each color's image would be printed and superposed to one another in accordance with an expected relationship to one another. For a manual operation, as above, an operator would start a print process, and after each image has been printed along the moving web material, would look at the final printed product and check as to whether or not registration of all color images is within preferred tolerances. Checking for registration of the images can be quite time consuming as an operator must determine registration of each color visually possibly with the help of a visual aid. In a newspaper type operation, such would entail looking at the printed, cut and folded newspapers to check color registration. The operator would also close this control loop by then manually adjusting any one or more print cylinders in one or both of its adjustment directions. Such a manual operation tends to produce waste product because all newspapers or the like that are printed during the adjustment period become waste. And, all product within the printing system, as will include multiple print stations, prior to each adjustment becomes waste. Typically, adjustments for image registration are needed in particular during a start up of a print run and during times of changing the web material, as such are typically provided in roll form and need to be changed on the fly during a print run.

Automatic systems with a closed feedback control system have been developed. For example, closed loop control systems for color printing utilizing a vision system and control logic for automated adjustment of print cylinders via stepper motors are commercially available from Nela, Inc, the assignee of the present invention, under the trade name designation OnPress Register Control systems. Such systems typically rely upon cameras that capture an image of the registration marks after each is printed and provide digital data of the captured image to a control processor, which identifies each color's registration mark and determines the appropriate corrections to be taken for each print cylinder to get the images superposed within a desired tolerance. Such control systems monitor the images throughout a print run and make adjustments as necessary any time during such a print run. These systems significantly reduce the amount of waste in that adjustments are made more quickly than with a manual control system and also in that misprinted material within the print system is minimized by reading the registration marks before making the final product.

However, such automatic closed feedback print systems are more expensive and require more installation effort than manual print systems. Moreover, the cost and effort needed to retrofit or convert current manual systems can be prohibitive.

### SUMMARY

The present invention is directed to systems and methods for controlling a printing press operation for alignment of plural images as are superposed onto one another. In particular, plural images are aligned to one another as part of a color printing operation utilizing plural printing stations where registration marks associated with the plural respective images can be aligned to one another based upon an open loop feedback of registration information. Preferably one or more data sources, such as cameras, capture the registration marks and digitize the data so that alignment or misalignment can be determined based upon tolerance limits. Systems and methods of the present invention provide for real-time monitoring of image alignment so that an operator can quickly and easily make adjustments to printing cylinders to correct image alignment.

In one aspect, the present invention is directed to a method of controlling a printing press system comprising a plurality of print stations that print different color images from one another onto a moving web, wherein the method comprising the steps of imaging at least a portion of a printed image on the web as produced from each of the plurality of print stations at the same time and location after each of the plurality of images have been superposed to one another on the web; determining from data obtained by the imaging step whether one printed image is misaligned with respect to another printed image; and transmitting alignment data to a display device for displaying such alignment data so that an operator of the printing press system can have real time feedback of alignment data of the printed images to one another and so that the operator can cause adjustment to one or more components of the printing system for changing alignment.

Preferably, a timing signal is sent to an imaging station for causing the imaging step from an encoder positioned to monitor web movement. Moreover, the imaging step can comprise the imaging of a plurality of color images that when superposed together create a multi-color image, the determining step can comprise determining alignment of each of the color images of the multi-color image to one another, and the transmitting step can include data being sent to the display with respect to each color image of the multi-color image.

Preferably also, the displaying step comprises showing a plot field with an indicator mark related to a base color image along with a plurality of other indicator marks as related to the other color images that make up the multi-color image. The displaying step can further include showing quantitative information so that adjustment of printing components can be affected to the degree indicated to an operator.

A further step can include a step of installing an open loop control system comprising an imaging station, a data processing station and a display device to a manually adjustable printing system prior to conducting the imaging step.

In another aspect, the present invention is directed to a system for open loop control for monitoring and providing image alignment information to an operator of a manual printing system comprising an imaging station, a data processing station and a display, the system capable of performing the method steps of imaging at least a portion of a printed image on the web as produced from each of the plurality of print stations at the same time and location after each of the plurality of images have been superposed to one another on the web; determining from data obtained by the imaging step whether one printed image is misaligned with respect to another printed image; and transmitting alignment data to a display device for displaying such alignment data so that an operator of the printing press system can have real time feedback of alignment data of the printed images to one another and so that the operator can cause adjustment to one or more components of the printing system for changing alignment.

### BRIEF DESCRIPTION OF THE DRAWINGS

FIG. 1 is a side schematic illustration of a printing system including multiple printing towers for plural printing press stations having features of an open loop control system of the present invention;

FIG. 2 is a schematic illustration of an open loop control system in accordance with the present invention for monitoring and providing real-time operation data related to image alignment as relevant to a printing press operation;

FIG. 3 is a front view of a display device illustrating aspects of the present invention for providing real-time indications to a printing press operator of alignment aspects of printed images as are monitored and can be controlled in accordance with the present invention;

FIG. 4 is a a front view of a display device similar to FIG. 3 illustrating another aspect of the present invention for allowing selective monitoring of printing press operations by a printing press operator;

FIG. 5 is a front view of a display device similar to FIG. 3 illustrating another aspect of the present invention for tracking alignment aspects of printing press operations by a printing press operator;

FIG. 6 is a front view of a display device similar to FIG. 3 illustrating another aspect of the present invention for allowing selective control of the monitoring process for printing press operations by a printing press operator;

FIG. 7 is a front view of another display device in accordance with the present invention illustrating another aspect of the present invention for monitoring a plurality of data sources or cameras at the same time and in real-time with alignment information related to printing press operations to a printing press operator;

FIG. 8 is a front view similar to FIG. 7 showing the selection of two cameras, camera one and camera two, positioned side-by-side and including both the alignment plot and numerical data of alignment; and

FIG. 9 is a front view similar to FIG. 7 showing a single source, camera one as singly provided on a display.

### DETAILED DESCRIPTION

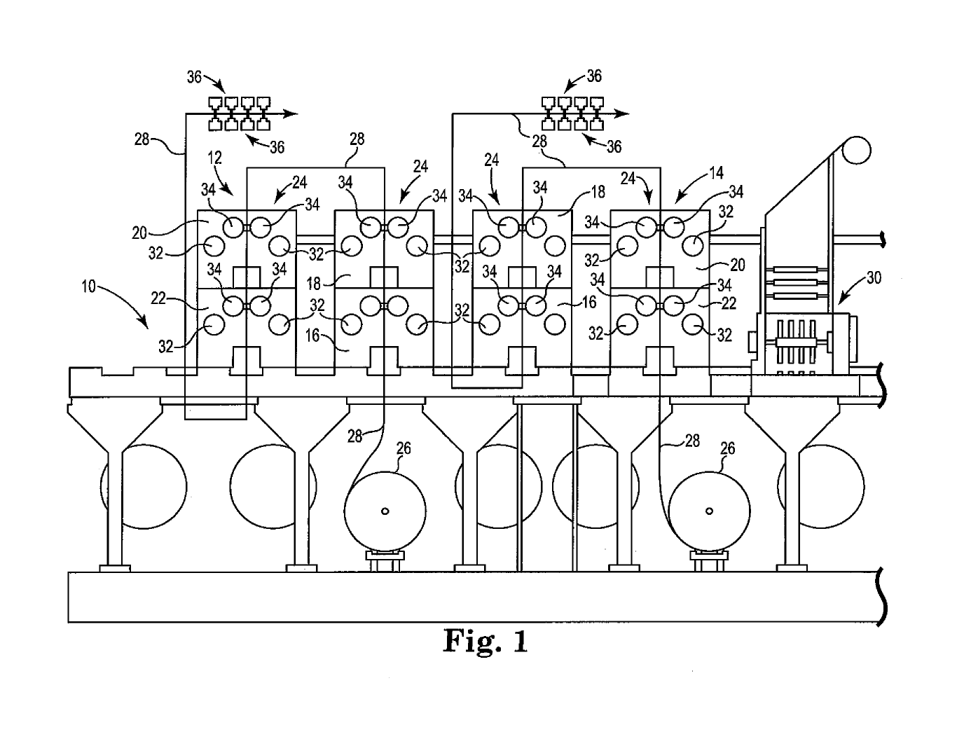

With reference to the attached figures, wherein like components are labeled with like numerals throughout the several figures and initially to FIG. 1, a printing system 10 is illustrated including a first printing press section 12 and a second printing press section 14. A printing system can include any number of such printing press sections. In the illustrated embodiment of the printing system 10, each of the first and second printing press sections 12 and 14 comprise multi-color print operations including a first printing station 16, a second printing station 18, a third printing station 20, and a fourth printing station 22. As described above within the Background section, four stations are preferable for printing full color by way of multi-color imaging process. One of the stations 16, 18, 20, and 22 can for example print a cyan image, another a magenta image, another a yellow image, and another a black image. More or less of such color stations are specifically contemplated as being within the subject of the present invention. A CMYK color print system is illustrated with four stations, while other commercial printing operations can have seven such color stations or more for enhanced full color printing.

According to the illustrated printing system 10, the stations 16, 18, 20, and 22 are arranged in pairs within towers 24. Such towers 24 are commonly used within printing systems and can comprise any number of stacked stations. In the embodiment of FIG. 1, the first and second stations 16 and 18 are stacked as a tower 24 and the third and fourth stations 20 and 22 are stacked as another tower 24. Supported below the printing system 10 at locations for each printing section 12 and 14, paper rolls 26 are provided. These paper rolls 26 can be conventionally supported to permit rotation and thus unwinding of a paper web 28 as such paper web can be guided through the printing sections 12 and 14, such as schematically shown in FIG. 1. In this embodiment of the printing sections 12 and 14, the paper web 28 is wound along a guide path comprising first passing through a tower 24 comprising the first and second printing stations 16 and 18 and then through an adjacent tower 24 comprising third and fourth station 20 and 22. After leaving both towers 24, the paper web 28 is schematically shown as wound about and eventually leading to a folding and chopping station 30, as such station is conventionally known for the purpose of cutting and folding the paper web 28 into newspaper pages, for example.

Within each printing station 16, 18, 20, and 22, a print cylinder 32 is provided, which print cylinders each comprise typically a plurality of lithographic plates as are also conventionally known. Also illustrated adjacent to each printing cylinder 32 is an ink transfer roller 34 that transfers and applies ink to the paper web 28 in well known manner. The print cylinders 32 are also preferably supported within each printing station 16, 18, 20, and 22 so as to be adjustable in at least two directions that allow for image adjustment from each station 16, 18, 20, and 22 relative to each other. Print cylinders 32 can be provided with one or more lithographic plates. Typically, a print cylinder 32 will have between one and twelve plates, although more could be contemplated. Each plate is to correspond to a printed image, such as to a newspaper or the like, as such images are to be printed in succession. For example, with two such plates, two successive pages of a newspaper could be printed from a single revolution of the print cylinder 32. As such, alignment of the two images for a particular color application would be similarly aligned to one another based upon the fixation of the lithographic plates onto the print cylinder 32.

As discussed above within the Background section, it is preferable that each print cylinder 32 (typically each print and transfer cylinder combination) be adjustable in a vertical sense, which means a translation of the axis of the print cylinder 32 vertically (which is the direction of the paper web 28 through the tower) and side-to-side, which means a translation along the axis of the print cylinder 32. With at least these two adjustable components of the print cylinders 32, one or more color image as produced from the one or more plates of a print cylinder 32 of any one station 16, 18, 20, and 22 can be adjusted so as to be in proper registration with any other corresponding color image as produced from each of the other stations 16, 18, 20, and 22. These translations or movements for adjustment of the cylinders 32 can be provided by manual means or with drive means, as such are both conventionally known for providing a motive force to cause print cylinder adjustment. The present invention is not specifically directed to the manners by which the print cylinders are actually translated or moved, but is directed to a control system for initially checking image registration to one another and to providing feedback information to an operator so that the proper adjustments can be made. As examples, hand crank mechanisms are known for operator manual adjustment of each print and transfer cylinder combination in these two directions. Likewise, motors can be utilized to impart such movements as they can be operatively connected with the vertical and side-to-side adjustment mechanism. With remote motor control, an operator can work from a console or the like having switches for any number of motor activations for any number of presses. By the present invention, an operator can be effectively provided with alignment information in real time as an open loop control system so that the operator can complete the loop by manually performing the alignment adjustments for any number of printing presses whether by actually adjusting the cylinders or by remote control of cylinder adjustment motors (not shown).

As also discussed above within the Background section, each station typically prints one color of a multi-color image which when properly printed on top of one another creates a full color image to the paper web 28. In order to provide a measurable indication of registration of the colors with respect to one another, it is known to print a registration mark along with each color image. Then, by comparing the registration marks to one another and to an expected relationship of them to one another, misalignments of one image to another can be accurately measured so that print cylinder adjustments can be determined. Where multiple lithographic plates are mounted to a print cylinder 32, it is preferable that each image (which image number corresponds to the number of lithographic plates) be provided with its own registration mark. Techniques for determining adjustment of the cylinders 32 with respect to one another are also well known. For example, it may be preferable to adjust the three color images to register to the black image within a set tolerance limit.

Registration marks can be designed and utilized in many different ways. Preferably for each printed color, one or more marks are printed along with the color image. One scheme associates a pair of dots for each color where each color is distinguished from the others by size of the dots and spacing between. Or, the marks may simply be distinguished from one another by color. In any case, it is important that the registration marks be set up so as to print in a known specific relationship to one another, so that variations from such a known an expected relationship can be determined based upon a visual inspection. Many other schemes are contemplated. As will be apparent from the following discussion, varying marks of one color to another by size and spacing is advantageous in that they are distinct from one another even as viewed in black and white.

It is a purpose of the present invention to provide instant feedback to an operator of a printing system so that images can be aligned to one another quickly and effectively to minimize waste of time and materials. In order to do this, a first step is to view the registration marks as printed by each of the stations 16, 18, 20, and 22 as close as practical to the paper web leaving the last of the stations. Preferably, viewing is conducted by an image capturing technique including the use of an imaging device or camera 36 as provided to view each side of the paper web 28. Cameras 36 are schematically illustrated in FIG. 1 as being able to capture the registration marks of each of the four printed images by color and to digitize the location of each registration mark or marks (in the case of a pair or more of marks in a known association) relative to a fixed frame into digital data to be transmitted to a control system, as further discussed below. Such an imaging device and step can be conducted with a color camera or a black and white camera if the marks of one color can be determined from those of another color.

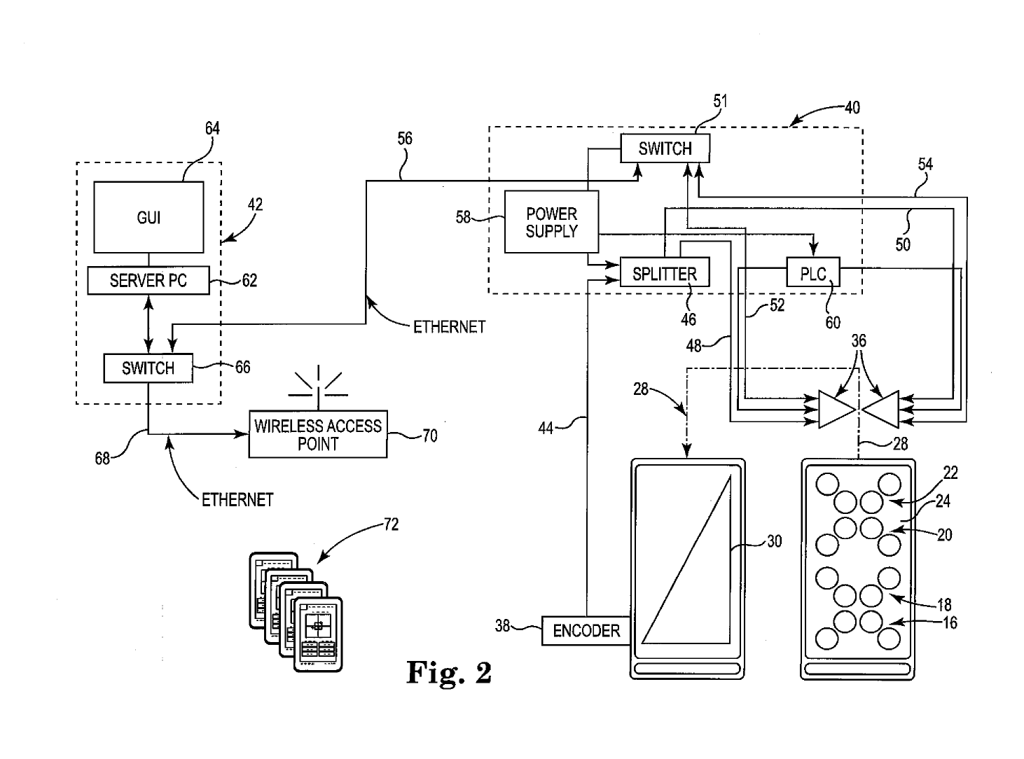

In FIG. 2, a print tower 24 is schematically illustrated as comprising print stations for each of the four image colors that are preferably printed for a full color image. A paper web 28 is shown leading from the tower 24 to a folding and chopping station 30. Image capturing cameras 36 are positioned as the paper web 28 exits the tower 24. The cameras 36 are preferably controlled so as to periodically capture images of each side of the printed paper web 28 based upon an expectation of the registration marks as printed for each color image to be viewable at the camera location. Such timing can be calculated based upon the known parameters of dimensions and web speed and/or can be determined empirically during a print run.

To facilitate effective image capturing, it is preferable to utilize strobe lighting as may be incorporated into the cameras 36 or as may be separately provided in combination with the cameras 36. Control of this strobe lighting is facilitated by a signal provided from an encoder 38 that is schematically illustrated as positioned adjacent to the folding station 30 for the purpose of monitoring web speed. In particular, the encoder 38 can be operatively connected to a rotational element, such as a roller element, as provided at any location along the web 28 from which web speed can be determined in a known manner.

A distribution panel 40 is schematically illustrated in FIG. 2 as may be provided proximate to a tower 24 for controlled distribution of power and data between the encoder 38 and each camera 36. The distribution panel 40 also preferably controls data between each camera 36 and a data processing station 42 described in more detail below.

The encoder 38 preferably monitors web speed data and specifically can provide a signal to the distribution panel 40 at set times, which signal can represent a timing signal for actuation of the strobe lighting and camera image capture. Again, the timing signal can be set to be provided by the encoder 38 by calculation or empirical determination of an expected timing of the positioning of each registration mark for image capture by the cameras 36 as specifically positioned in a known relationship with the positioning of the encoder and based upon web speed and dimensional parameters. As also schematically shown, a timing signal from the encoder 38 is sent via a data line 44 to a signal splitter 46 that provides the timing signal from the encoder 38 to each camera 36 based upon receipt of the timing signal from the encoder 38. Data lines 48 and 50 facilitate transfer of the timing signal to the cameras 36, respectively, so as to cause camera and strobe activation at the expected time of capture of the registration marks from each side of the web 28.

Each camera 36 is also preferably electronically connected to the distribution panel 40, in particular, to a data switch 51 provided within the distribution panel 40. Data lines 52 and 54 represent such digital communication and connection between the cameras 36 and the data switch 51. The data switch 51 and signal splitter 46 are conventional components as are commercially available and incorporated within the distribution panel 40 of a preferred control system of the present invention. A further data line 56 provides digital communication and connection between the data switch 51 and the data processing station 42.

As each of the cameras 36 and their strobes, the signal splitter 46 and data switch 51 require power for operation, a power supply 58 is also schematically illustrated as it is preferred to be incorporated within the distribution panel 40 and as it is operatively connected to each of these components by conventional wiring. Within the wiring between the power supply 58 and each of the cameras 36, a programmable logic controller 60 is preferably provided as also schematically depicted for the purpose of enabling and disabling power for each camera 36. Such a programmable logic controller 60 is a conventionally used component of such camera system and can be connected between the power supply and cameras in a well known manner. A preferable power supply suitable for these purposes can comprise a 24V DC power supply, as also conventionally available.

As above, the data line 56 can comprise an Ethernet type cable or the like so that the switch 51 can communicate with the data processing station 42 as such can be located at any location relative to a printing system 10. The data processing station 42 is schematically shown as including a programmable data processor 62 as such may comprise a commercially available personal computer or server, as are well known. The data processor 62 preferably communicates with a graphical user interface 64 as can be provided as a touch screen type display for example, for systems operator control. A data switch 66 provides for data communication not only to and from the switch 51 of the distribution panel 40 and the data processor 62, but also to and from the data processor 62 with other objects of the present invention, such as wireless personal communication devices described in more detail below. As also illustrated, it is preferred that the switch 66 provide a data connection, such as by another Ethernet cable, to a wireless access device 70 as is preferably positioned at a location proximate to a printing system 10 so that data can be available at the print site in real time based upon registration mark information. It is noted that the switch 66 and wireless device 70 can be integrated together within a single hardware device or they can be separately provided.

The data processing station 42 can also be conventionally associated with any number of display devices or monitors that can be connected to the data processing station 42 via the switch 66 or otherwise. Such display devices can provide the communication to an operator as described below. These display devices can comprise either fixed or mobile devices that may be connected by way of fixed wiring or by way of wireless connectivity, as also described more below. Also, it is contemplated that any number of data servers or data processing stations can be operatively connected together in order to share physical resources, such as data sources as may comprise any number of cameras in accordance with the present invention.

In operation of a print tower 24, for example as schematically illustrated in FIG. 2, each camera 36 captures registration mark images under the timing control from the encoder 38. Assuming that the registration marks of each sequential multi-imaged print are captured and framed by each camera 36, registration mark location data for each registration mark can be electronically transmitted via the switch 51 to the data processor 62. It is preferable that each registration mark is independently determined along with location data relative to a fixed frame. With this information compiled together, the information of relative locations of one registration mark to the others can be determined. The registration marks of each color image can be distinguished from one another by just color or by color and/or other mark features. Any such determinations and relative location data can be made by the data processor 62 under the control of a systems operator, as known.

In the typical case where more than one lithographic plate is mounted to each corresponding print cylinder 32 of a printing press, such as at 12 or 14 in the FIG. 1 schematic illustration, each image is preferably provided with a registration mark, as discussed above. This allows an operator to decide which image that results from a single revolution of a print cylinder is to be monitored for these alignment purposes. For example, with a two plate set up for each print cylinder of a four color print, two full color images would be produced by a single revolution of each print cylinder. On the paper 28, the two images would be printed in succession, each image with its own set of registration marks (e.g. four registration marks associated with the four colors of the full color print). By controlling the timing of the camera activation, as described above, the operator can select which of the two images is to be monitored. This can be beneficial where an image of one of the multiple printed images requires greater alignment than another. For example, a full page color image may be more significant to the printer than another image of less color, smaller size or the like. The operator can thus select a preferred image out of the multiple images as may be printed from a single cylinder revolution.

In one aspect of the present invention, portable data devices 72 can be used to communicate information in usable form to a printing press operator. More preferably, remote data devices 72 as are commercially known as data tablets can be utilized as they are easily portable and provide a touch screen interface with a relatively large data display. Moreover, such commercial data tablets allow for the loading of applications as can be designed for specific control and display features, such as for providing image location information and other printing information to an operator of a printing press operation as described below. It is contemplated that other data devices can be utilized for providing data to or from an operator including personal computers, lap top, smart phones. It is also contemplated that only one or more display devices may be provided for operator viewing as may be portable or mounted, for example, to a print tower. For example, one or more display monitors can be mounted at an operator's console so that the operator can monitor any number of data sources (cameras) as may be provided for any number of press operations. Any such data devices can be hard wired to the data processing station 42 or can communicate via a wireless device 70. A data device 72 can be provided on a printing system basis, an operator basis, or for each print tower as desired. It is also preferable that a systems operator have access to the same information as supplied to a printing press operator by way of the graphical user interface.

The data processor 62 also preferably conducts a step of determining whether or not each successive print is within alignment tolerances. This can be done by first setting a first registration mark as a fixed or base target and then by a comparison of each other registration marks to the target mark. From know dimensional data of the registration marks and image size, specific measurements with respect to alignment in both X and Y directions can be determined for each color image. The X and Y directions can be directly related to print cylinder adjustment as described above. Thus, for each image captured, a determination as to whether that specific print is within tolerances or not can be made. By combining the result of each alignment determination with the counter data as determined from the encoder timing signals, the number of good and bad prints can also be counted. An operator could thus be easily advised on the timing of a bad print as soon as it is imaged after leaving a tower and the number of bad prints that are outside of the tolerance limits. Thus, even with a fully manual control of the adjustment mechanisms of a print cylinder, the number of bad prints can be minimized.

It is also preferable that each captured image be date and time stamped and that each captured image be saved in memory of the data processing station 42 so that in addition to the real time monitoring of the registration information, the data and captured images can be reviewed at a later time for analysis. Such saved data can thus provide documentation of a print run as to the number or percentage of printed images that were within alignment or not. The captured images can provide proof of a successful print run with alignment of a quantity of printed images within registration tolerance.

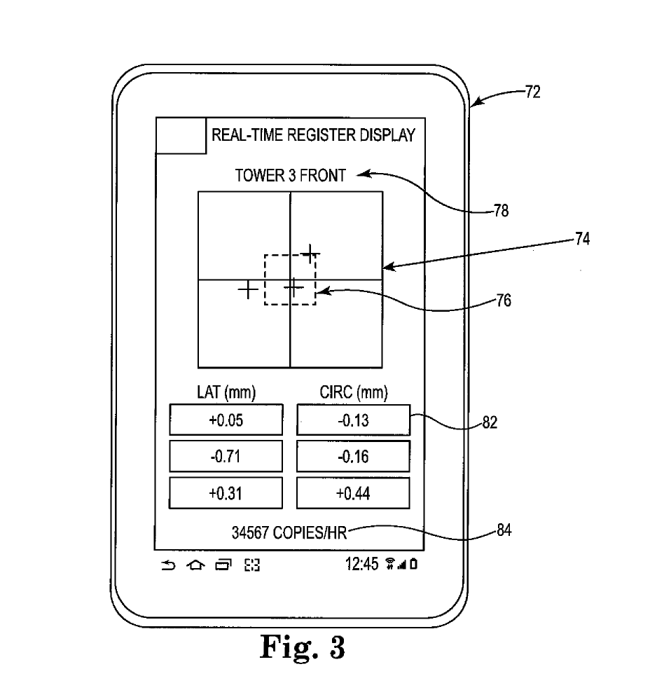

In FIGS. 3-6, examples of various displays are illustrated for a preferred portable data device 72 of the present invention. Each of the illustrated displays as contemplated and shown are based upon the data obtained as described above with respect to registration mark location data for each printed color and the number of prints as are made, for example, by counting encoder timing signals. Graphics for each display can be generated within the data processor 62 (similar to a display provided to a computer monitor) or by way of an application loaded to a portable or remote data device.

FIG. 3 shows one preferred display for a remote data device 72 providing alignment data is various different ways. For example, an X-Y plot is shown at 74. Within this plot field, a black registration mark image is set at the centerpoint (which black registration mark is not visible in FIG. 3 because it is aligned with a set of cross axes) along with three colored registration marks as are plotted relative to the black mark based upon the image information captured by a camera 36, as above. FIG. 3 illustrates three other registration marks with the understanding that any number of such registration marks could be provided based upon the number of colors that are printed, it being preferable that each color printed have an associated registration mark. On a color screen, it would also be preferable that each registration mark be colored based upon the color that they represent. Otherwise or with a monochromatic screen, the registration marks can be distinguished from one another by shape size, or other visually determinable manner.

Preferably an area defining the tolerance limit for registration alignment is also indicated, such as shown by a dashed box 76. The graphically displayed elements are preferably shown to the operator in color so that it is easy for the operator to identify which one or more print cylinders 32 is/are to be adjusted and by what relative amount in the X and Y directions. The graphic indicators for each registration mark can be shaped differently from one another or can include other distinguishing features if desired instead of using colors or along with the different color marks.

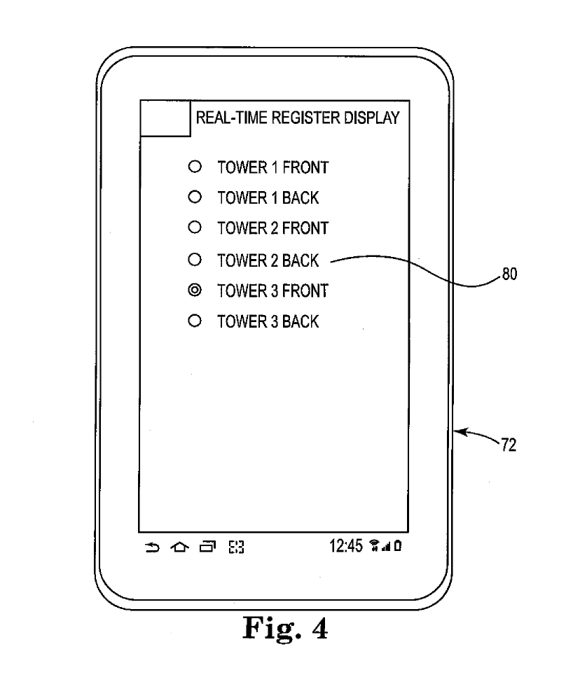

Preferably above the plot 74, the specific print tower or press is indicated along with an indication of whether you are viewing results for the front or back side of the web 28. Alternative, each camera can be assigned a number or other select notation so that an operator can be apprised of which camera or data source is represented on the screen. It is contemplated that the display can include a means by which the display screen can be changed from one tower or press to another. In conventional remote data devices that are commercially available, it is common to provide a button that takes the user to a selection screen from which a specific tower or press can be chosen either by button or touch screen or for a user to scroll or switch screen display by button or touch screen. FIG. 4 shows a screen by which an operator can select which specific tower they wish to monitor from a listing 80. Preferably, this list of selections is populated from the data processor 62 based upon which printing systems, towers, or presses that are in operation.

Referring back to FIG. 3, in addition to the plot 74 showing an operator of alignment information graphically, it is also preferred to provide specific quantitative information, as shown at display area 82. In this illustrated example, alignment information for each of the three color cylinders, excluding the black print cylinder as being the base, is provided for both X and Y adjustments by specific numeric amounts. These numbers preferably directly relate to the distance that an operator is to adjust each cylinder in both directions to be is full alignment. The alignment numbers and or the box itself can be color-coded based upon the monitored color. Another feature of preferred indicator boxes of the display area 82 is the use of color as an indication of whether or not the number is within a tolerance limit. For example, different color borders, number or backgrounds can be used, such as red and green, to indicate quickly to an operator whether the reported number for one of the monitored colors is in or out of tolerance. Tolerances can be different from one print job to another. In this example, the term “Lat” means an adjustment of a print cylinder side-to side (the X direction as viewed in the plot 74) while the term “Circ” means an adjustment of the cylinder vertically as a translation of axis of the print cylinder (the Y direction as viewed on the plot 74). At the bottom portion of the display example of FIG. 3, a counter 84 is also illustrated showing for example a running rate number of prints per time period.

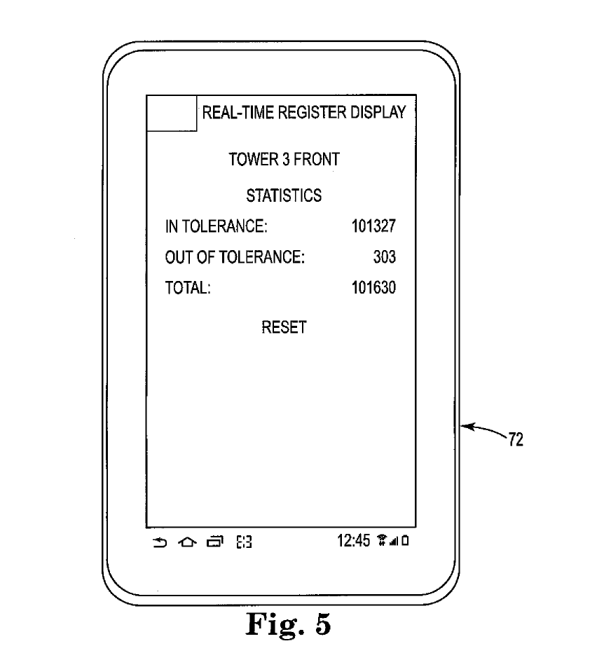

FIG. 5 is another preferred view that may be available to an operator in accordance with the present invention. This display can provide statistical information to the operator based upon the selected print tower or press. Preferably such a view would be available from one or more of the other screens, for example, permitting an operator to go to the statistics screen directly from the alignment information screen of FIG. 3. Alternatively, a home or menu screen can be provided from which each screen display can be selected.

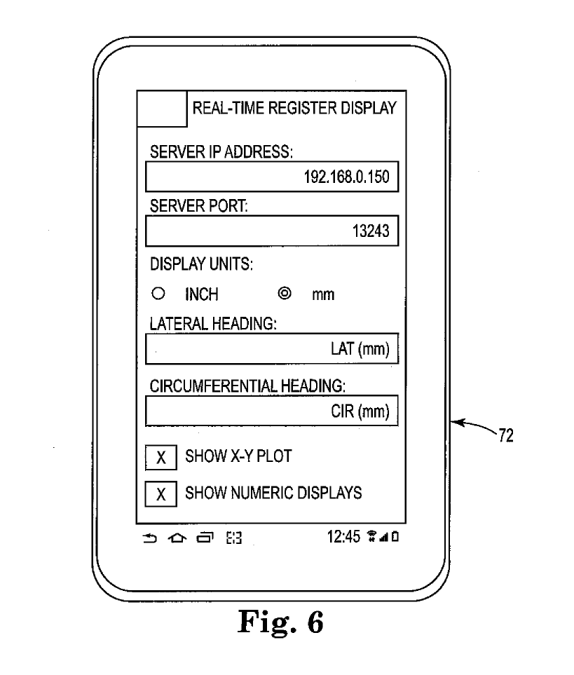

FIG. 6 shows another preferred type screen that can allow an operator to select the types of screen displays that they may prefer to see and/or to potentially choose between optional ways of displaying similar information, i.e. graphical vs. quantitative, digital vs. analog, metric vs. English units, etc. As shown, information regarding connectivity and the like can also be displayed, for example, to verify that the device is properly connected or enabled.

As above, any number of such remote data devices 62 can be utilized for providing such information of a printing system to any number of locations or operators. By utilizing a wireless device 70 for data communication to the remote data devices, it is easy to add or remove such devices from usage. Other screen displays are contemplated as well. It additional data is determined with respect to any printing operation, such a by the addition of other sensors, or by utilizing captured or sensed information in different ways, graphic displays can be designed to show such information in any number of different ways. However, with remote device 62 of the present invention, it is desirable that at least real time alignment information be provided to an operator. This control system is thus open loop so that an operator can close the loop by performing the adjustment step or steps as needed and as indicated to the operator in real time during a printing operation.

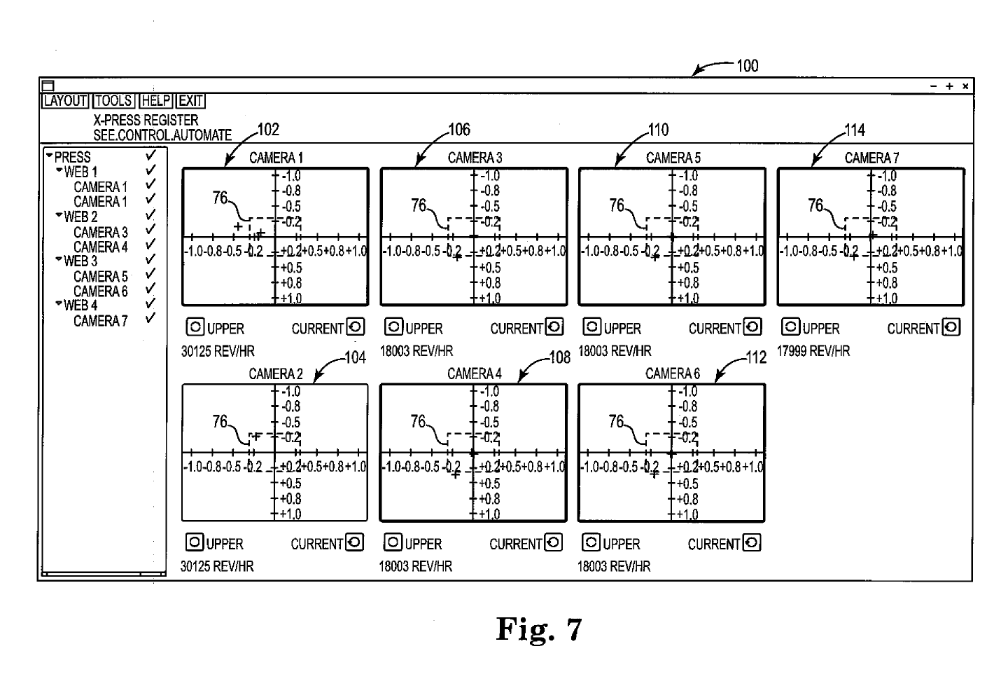

An alternative data display is illustrated within FIGS. 7, 8 and 9, which is a display as may be preferably provided onto a relatively large display monitor for example as may be provided mounted to an operator console for monitoring of a number of data sources or cameras. As illustrated seven cameras are monitored on a single display screen as represented by alignment plots 10, 104, 106, 108, 110, 112, and 114, respectively, for each camera. It is understood that any number of sources can be represented. What can be easily seen by this screen is that all of the cameras with the exception of camera two include at least one color that is out of alignment. This misalignment data can be seen by the registration marks as represented within and out of the respective tolerance boxes 76 for each plot 102-114. Moreover, it is preferred that the cameras out of alignment be otherwise highlighted for easy indication to an operator. For example, as illustrated, the plots 102, 106, 108, 110, 112, and 114 are highlighted by a bold border to indicate to the operator of an alignment issue. In contrast, the plot 104 representing camera two is not highlighted by a bold border, indicating that the colors are all within alignment based upon the predetermined tolerances. Such an indication can be provided instead by colors, such as red and green as discussed above, by varying the background color or look, or by other visually discernable manners.

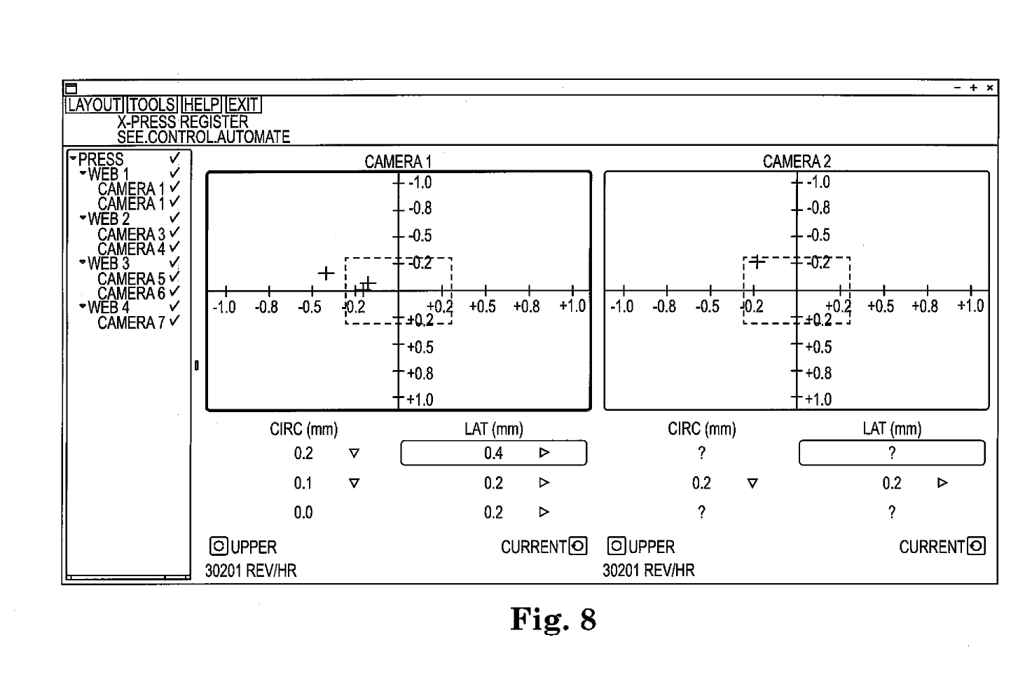

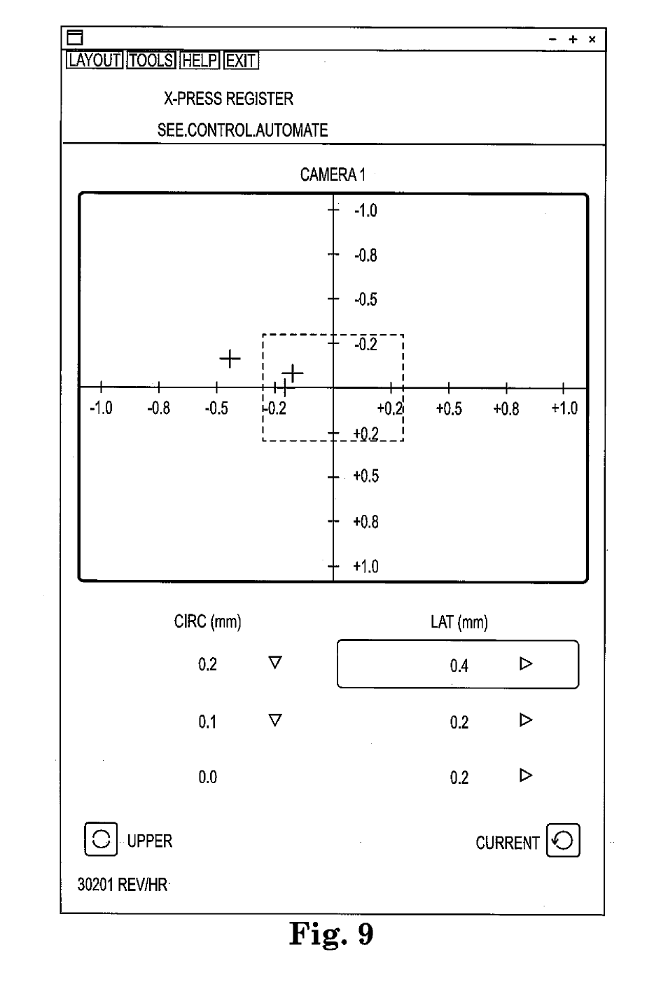

FIGS. 8 and 9 illustrate selectivity of the data sources as can be preferably displayed. For example, FIG. 8 shows the selection of two cameras, camera one and camera two, positioned side-by-side and including both the alignment plot and numerical data of alignment in a similar manner as discussed above. FIG. 9 shows a single source, camera one as singly provided on a display. It is preferable that an operator be able to select any number of data sources for representation with displays having the potential for differences by providing greater detail as the number of data source is limited.

1. A method of controlling a printing press system comprising a plurality of print stations that print different color images from one another onto a moving web, the method comprising the steps of:
imaging at least a portion of a printed image on the web as produced from each of the plurality of print stations at the same time and location after each of the plurality of images have been superposed to one another on the web;
determining from data obtained by the imaging step whether one printed image is misaligned with respect to another printed image;
transmitting alignment data to a display device for displaying such alignment data so that an operator of the printing press system can have real time feedback of alignment data of the printed images to one another and so that the operator can cause adjustment to one or more components of the printing system for changing alignment.

2. The method of claim 1, wherein a timing signal is sent to an imaging station for causing the imaging step from an encoder positioned to monitor web movement.

3. The method of claim 1, wherein the imaging step comprises the imaging of a plurality of color images that when superposed together create a multi-color image, the determining step comprises determining alignment of each of the color images of the multi-color image to one another, and the transmitting step includes data being sent to the display with respect to each color image of the multi-color image.

4. The method of claim 3, wherein the displaying step comprises showing a plot field with an indicator mark related to a base color image along with a plurality of other indicator marks as related to the other color images that make up the multi-color image.

5. The method of claim 4, wherein the displaying step further includes showing quantitative information so that adjustment of printing components can be affected to the degree indicated to an operator.

6. The method of claim 1, further including the step of installing an open loop control system comprising an imaging station, a data processing station and a display device to a manually adjustable printing system prior to conducting the imaging step.

7. A system for open loop control for monitoring and providing image alignment information to an operator of a manual printing system comprising an imaging station, a data processing station and a display, the system capable of performing the method steps of claim 1.
